(19) United States
(12) Patent Application Publication
(10) Pub. No.: US 2012/0049210 A1
(43) Pub. Date: Mar. 1, 2012

(54) ORGANIC EL DISPLAY UNIT AND ELECTRONIC DEVICE

(75) Inventor: Kazunari Takagi, Tokyo (JP)

(73) Assignee: SONY CORPORATION, Tokyo (JP)

(21) Appl. No.: 13/212,581

(22) Filed: Aug. 18, 2011

(30) Foreign Application Priority Data
Aug. 25, 2010 (JP) 2010-188589

(51) Int. Cl. H01L 33/08

(52) U.S. Cl. 257/88; 257/E33.012

(57) ABSTRACT

An organic EL display unit includes: an organic layer provided on a substrate; a plurality of pixels arranged in a display region on the substrate; and a dividing wall provided on the substrate and separates adjacent pixels out of the plurality of pixels. The dividing wall is composed of a laminated structure having two or more types of inorganic material films with different wet characteristics.

### BACKGROUND

The present disclosure relates to an organic EL display unit that emits light by using organic electroluminescence (EL) phenomenon and an electronic device including such an organic EL display unit.

As development of information and communication industry has been accelerated, a display device having high performance has been demanded. Specially, as a next generation display device, an organic EL device has attracted attentions. As a self-luminous type display device, the organic EL device has an advantage that the view angle is wide and the contrast is excellent. In addition, the organic EL device has an advantage that the response time is short.

A light emitting layer and the like forming the organic EL device are broadly classified into a low molecular material and a polymer material. In general, it is known that the low molecular material provides higher light emitting efficiency and a longer life. In particular, the low molecular material provides a higher performance for blue.

Further, regarding a method of forming the organic film thereof, the low molecular material is formed by dry method (evaporation method) such as a vacuum evaporation method, and the polymer material is formed by wet method (coating method) such as spin coating, ink jet method, and nozzle coating.

The vacuum evaporation method has an advantage that a formation material of the organic thin film is not necessarily dissolved in a solvent, and a step of removing the solvent after forming the film is not necessitated. However, the vacuum evaporation method has disadvantages as follows. That is, separate coating by a metal mask is difficult. In particular, in forming a large panel, the vacuum evaporation method leads to high facility manufacturing cost, is difficult to apply applied to a large screen substrate, and is not suitable for mass production. Thus, the ink jet method and the nozzle coating method by which a large display screen area is relatively easily realized has attracted attentions.

However, in a case that an organic material is dropped onto respective pixel regions by using, for example, the ink jet method, there has been the following disadvantage. That is, in order to uniformize the film thickness of the organic layer in each pixel, lyophilic property is requested for a dividing wall that separates adjacent pixels (partitions the pixel regions). Meanwhile, in order to accurately fill an organic material solution into a given position in each pixel, liquid repellency is requested for the dividing wall. Thus, it has been difficult to achieve both film thickness uniformity of the organic layer and filling position accuracy of the organic material solution.

Thus, the following method has been proposed. In the method, the foregoing dividing wall has a two-layer structure composed of a first dividing wall made of an inorganic material showing lyophilic characteristics and a second dividing wall made of an organic material showing liquid repellency, and thereby both film thickness uniformity of the organic layer and filling position accuracy of the organic material solution are achieved (for example, see Japanese Unexamined Patent Application Publication Nos. 2007-5056, and 2008-243406, and Japanese Patent Nos. 3823916, and 4336742).

### SUMMARY

In the foregoing dividing wall having the two-layer structure, the filling position accuracy of the organic material solution (in addition, prevention of short circuit with an upper electrode due to wet on the dividing-wall-side face, inter-pixel leakage and the like) is realized by the second dividing wall showing liquid repellency. Further, in order to prevent a state that the organic material solution is repelled by the second dividing wall in the course of drying and the film thickness becomes nonuniform, film thickness uniformity of the organic layer is realized by the first dividing wall showing lyophilic characteristics.

However, in the dividing wall having the two-layer structure, the first dividing wall made of the inorganic material and the second dividing wall made of the organic material should be formed by different steps, and thus the manufacturing cost becomes high. In particular, in the case where the organic layer has a laminated structure composed of a plurality of layers, the first and the second dividing walls should be formed in accordance with each film thickness of each layer, and thus the number of steps is increased by just that much, leading to further cost increase. Accordingly, in the existing method, it has been difficult to improve display image quality (decreasing short circuit with the upper electrode, inter-pixel leakage and the like and improving film thickness uniformity of the organic layer) while achieving low cost.

In view of the foregoing disadvantages, in the present disclosure, it is desirable to provide an organic EL display unit that is able to improve display image quality and achieve low cost and an electronic device.

According to an embodiment of the present disclosure, there is provided an organic EL display unit including an organic layer provided on a substrate, a plurality of pixels arranged in a display region on the substrate, and a dividing wall provided on the substrate and separates adjacent pixels out of the plurality of pixels. The dividing wall is composed of a laminated structure having two or more types of inorganic material films with different wet characteristics.

According to an embodiment of the present disclosure, there is provided an electronic device including the foregoing organic EL display unit according to the embodiment of the present disclosure.

In the organic EL display unit and the electronic device according to the embodiment of the present disclosure, the dividing wall that separates adjacent pixels is composed of the laminated structure having two or more types of films with different wet characteristics. Thereby, in forming the organic layer in the pixel by using wet method (coating method), filling position accuracy of an organic material solution is secured, and short circuit with an electrode due to wet on the side face of the dividing wall, inter-pixel leakage and the like are inhibited by a film with relatively low wet characteristics (a liquid repellent film). Further, in the drying step, the organic material solution is prevented from being repelled, and variation of the film thickness in the organic layer is decreased by a film with relatively high wet characteristics (a lyophilic film). Further, two or more types of films with different wet characteristics are all made of an inorganic material film. Thus, the dividing wall composed of the laminated structure is able to be formed in a single step.

According to the organic EL display unit and the electronic device of the embodiment of the present disclosure, the dividing wall that separates adjacent pixels is composed of the laminated structure having two or more types of inorganic material films with different wet characteristics. Thus, filling position accuracy of the organic material solution is secured, short circuit with the electrode, inter-pixel leakage and the like are decreased, and film thickness uniformity of the organic layer is improved. At the same time, such a dividing wall is able to be formed in a single step. Therefore, while low cost is realized, display image is able to be improved.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the present disclosure, and are incorporated in and constitute a part of this specification. The drawings illustrate embodiments and, together with the specification, serve to explain the principles of the technology.

FIG. 1 is a diagram illustrating a configuration of an organic EL display unit according to an embodiment of the present disclosure.

FIG. 2 is a diagram illustrating an example of the pixel drive circuit illustrated in FIG. 1.

FIG. 3 is a cross sectional view illustrating a structure of the display region illustrated in FIG. 1.

FIG. 4 is a cross sectional view illustrating a detailed structure of a main section of the organic EL display unit of each color illustrated in FIG. 3.

FIG. 5 is a flowchart illustrating main steps of a manufacturing method of the organic EL display unit illustrated in FIG. 1.

FIG. 6 is a cross sectional view illustrating the manufacturing method illustrated in FIG. 4 in order of steps.

FIG. 7 is a characteristics diagram illustrating an example of relation between a film formation rate and a contact angle in forming a dividing wall.

FIG. 8 is a cross sectional view illustrating a step following FIG. 6.

FIG. 9 is a cross sectional view illustrating a step following FIG. 8.

FIG. 10 is a cross sectional view illustrating a step following FIG. 9.

FIG. 11 is a cross sectional view illustrating a configuration of a main section in an organic EL display unit according to Comparative example 1.

FIG. 12 is a cross sectional view illustrating a configuration of a main section in an organic EL display unit according to Comparative example 2.

FIG. 13 is a cross sectional view illustrating a configuration of a main section in an organic EL display unit according to a first modification.

FIG. 14 is a cross sectional view illustrating a configuration of a display region in an organic EL display unit according to a second modification.

FIG. 15 is a flowchart illustrating main steps of a manufacturing method of the organic EL display unit illustrated in FIG. 14.

FIG. 16 is a plan view illustrating a schematic structure of a module including the display unit of the foregoing embodiment and the like.

FIG. 17 is a perspective view illustrating an appearance of a first application example of the display unit of the foregoing embodiment and the like.

FIG. 18A is a perspective view illustrating an appearance viewed from the front side of a second application example, and FIG. 18B is a perspective view illustrating an appearance viewed from the rear side of the second application example.

FIG. 19 is a perspective view illustrating an appearance of a third application example.

FIG. 20 is a perspective view illustrating an appearance of a fourth application example.

FIG. 21A is an elevation view of a fifth application example unclosed, FIG. 21B is a side view thereof, FIG. 21C is an elevation view of the fifth application example closed, FIG. 21D is a left side view thereof, FIG. 21E is a right side view thereof, FIG. 21F is a top view thereof, and FIG. 21G is a bottom view thereof

### DETAILED DESCRIPTION OF EMBODIMENT

An embodiment of the present disclosure will be hereinafter described in detail with reference to the drawings. The description will be given in the following order:
1. Embodiment (example in which an individual light emitting layer is provided for respective pixels for R, G, and B)
2. Modifications

First modification (example in which a lyophilic film is projected deeper than a liquid repellent film)

Second modification (example in which a blue light emitting layer is provided as a common layer for pixels for R, G, and B)
3. Application examples (examples of application to electronic devices)

### Embodiment

### Whole Configuration of Organic EL Display Unit

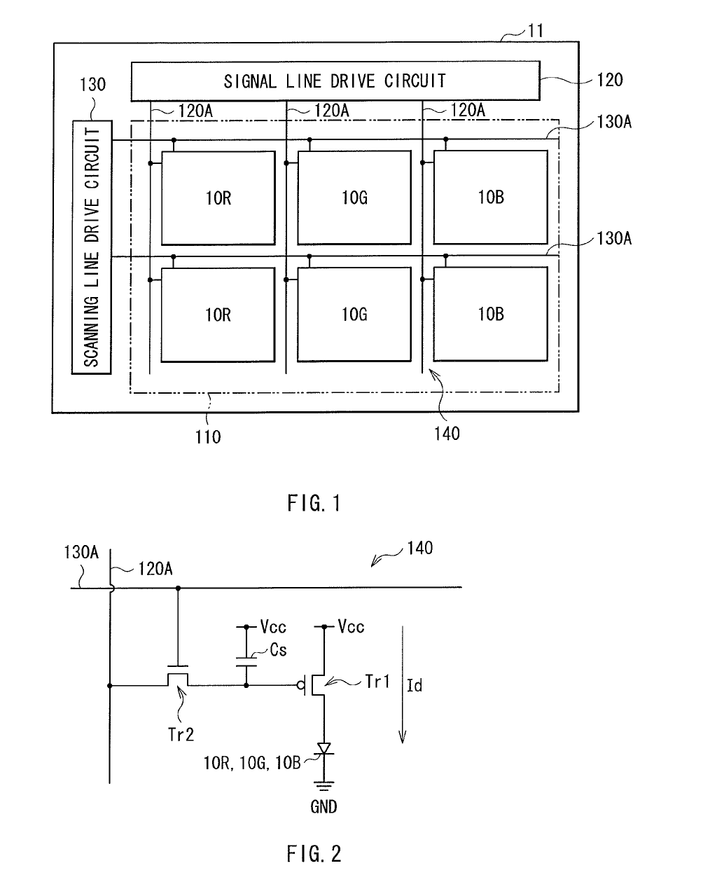

FIG. 1 illustrates a whole configuration of an organic EL display unit (an organic EL display unit 1 described later) according to an embodiment of the present disclosure. The organic EL display unit is used as an organic EL television device or the like. In the organic EL display unit, for example, as a display region 110, a plurality of red organic EL devices 10R, a plurality of green organic EL devices 10G, and a plurality of blue organic EL devices 10B described later are arranged in a matrix state over a substrate 11. A signal line drive circuit 120 and a scanning line drive circuit 130 that are drivers for displaying a picture are provided on the periphery of the display region 110.

In the display region 110, a pixel drive circuit 140 is provided. FIG. 2 illustrates an example of the pixel drive circuit 140. The pixel drive circuit 140 is an active drive circuit that is formed in a layer located lower than an after-mentioned lower electrode 14. The pixel drive circuit 140 has a drive transistor Tr1, a writing transistor Tr2, and a capacitor (retentive capacity) Cs between the transistors Tr1 and Tr2. Further, the pixel drive circuit 140 has the red organic EL device 1OR (or the green organic EL device 10G or the blue organic EL device 10B) serially connected to the drive transistor Tr1 between a first power line (Vcc) and a second power line (GND). The drive transistor Tr1 and the writing transistor Tr2 are composed of a general thin film transistor (TFT). The configuration thereof is not particularly limited, and may be, for example, inversely staggered structure (so-called bottom gate type) or staggered structure (top gate type).

In the pixel drive circuit 140, a plurality of signal lines 120A are arranged in the column direction, and a plurality of scanning lines 130A are arranged in the row direction. Each cross section between each signal line 120A and each scanning line 130A corresponds to one of the red organic EL device 10R, the green organic EL device 10G, and the blue organic EL device 10B. Each signal line 120A is connected to the signal line drive circuit 120. An image signal is supplied to a source electrode of the writing transistor Tr2 from the signal line drive circuit 120 through the signal line 120A. Each scanning line 130A is connected to the scanning line drive circuit 130. A scanning signal is sequentially supplied to a gate electrode of the writing transistor Tr2 from the scanning line drive circuit 130 through the scanning line 130A.

Further, in the display region 110, the red organic EL device 1OR generating red light, the green organic EL device 10G generating green light, and the blue organic EL device 10B generating blue light are sequentially arranged in a matrix state as a whole. In other words, in the display region 110, the plurality of pixels (the pixel for generating red light including the red organic EL device 10R, the pixel for generating green light including the green organic EL device 10G, and the pixel for generating blue light including the blue organic EL device 10B) are arranged in a matrix state.

### [Cross Sectional Configuration of Organic EL Display Unit]

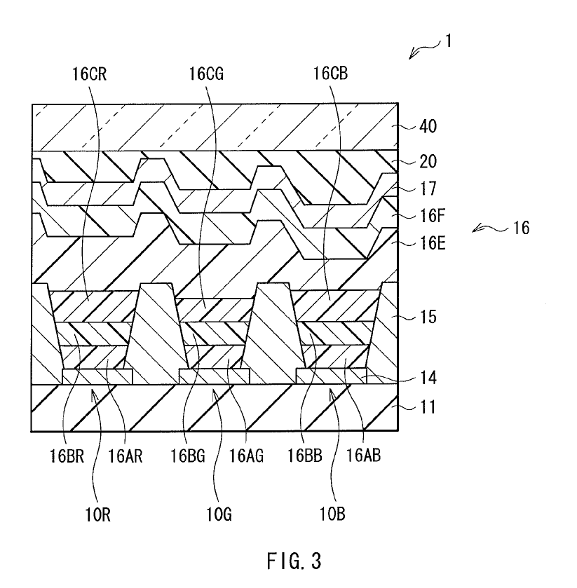

FIG. 3 illustrates a cross sectional structure of the display region 110 illustrated in FIG. 1. The red organic EL device 10R, the green organic EL device 10G, and the blue organic EL device 10B respectively have the following laminated structure. That is, the red organic EL device 10R, the green organic EL device 10G, and the blue organic EL device 10B have a structure in which the lower electrode 14 as an anode, a dividing wall 15, an organic layer 16 including a light emitting layer 16C described later, and an upper electrode 17 as a cathode are layered in this order from the substrate 11 side with the drive transistor Tr1 of the foregoing pixel drive circuit 140 and a planarizing insulating film (not illustrated) in between.

The red organic EL device 10R, the green organic EL device 10G, and the blue organic EL device 10B as above are coated with a protective layer 20. Further, a sealing substrate 40 made of glass or the like is bonded to the whole area of the protective layer 20 with an adhesive layer (not illustrated) such as a thermoset resin and an ultraviolet curing resin in between, and thereby the red organic EL device 10R, the green organic EL device 10G, and the blue organic EL device 10B are sealed.

### (Substrate 11)

The substrate 11 is a support body in which the red organic EL device 10R, the green organic EL device 10G, and the blue organic EL device 10B are arranged on one main face side. The substrate 11 may be a known substrate, and is made of, for example, quartz, glass, a metal foil, a resin film, a resin sheet or the like. Specially, quartz and glass are preferable. Examples of resin include a methacryl resin represented by polymethyl methacrylate (PMMA), polyester such as polyethylene terephthalate (PET), polyethylene naphthalate (PEN), and polybutylene naphthalate (PBN), and a polycarbonate resin. A lamination structure and a surface treatment that inhibit water permeability and gas permeability should be provided.

### (Lower Electrode 14)

The lower electrode 14 is provided on the substrate 11 respectively for the red organic EL device 10R, the green organic EL device 10G, and the blue organic EL device 10B. The lower electrode 14 has a thickness in the lamination direction (hereinafter simply referred to as thickness) of, for example, from 10 nm to 1000 nm both inclusive. Examples of material of the lower electrode 14 include a simple substance or an alloy of metal elements such as chromium (Cr), gold (Au), platinum (Pt), nickel (Ni), copper (Cu), tungsten (W), and silver (Ag). Further, the lower electrode 14 may have a laminated structure of a metal film made of a simple substance or an alloy of the foregoing metal elements and a transparent conductive film structured by, for example, an alloy composed of an oxide of indium and tin (ITO)/InZnO (indium zinc oxide)/zinc oxide (ZnO) and aluminum (Al). In the case where the lower electrode 14 is used as an anode, the lower electrode 14 is desirably made of a material having high hole injection characteristics. If an appropriate hole injection layer is provided, it is able to use a material that has a disadvantage of a hole injection barrier due to existence of an oxide film on the surface and a small work function such as an aluminum (Al) alloy as the lower electrode 14.

### (Dividing Wall 15)

The dividing wall 15 is intended to secure insulation between the lower electrode 14 and the upper electrode 17, and to obtain a desired shape of the light emitting region. That is, the dividing wall 15 is intended to separate adjacent pixels out of the plurality of pixels in the display region 110. Further, the dividing wall 15 also functions as a dividing wall in coating by ink jet method or nozzle coating method in the after-mentioned manufacturing step. The dividing wall 15 is provided with an aperture corresponding to a light emitting region. The organic layer 16 and the upper electrode 17 may be provided not only in the aperture but also on the dividing wall 15. However, it is only the aperture of the dividing wall 15 that emits light.

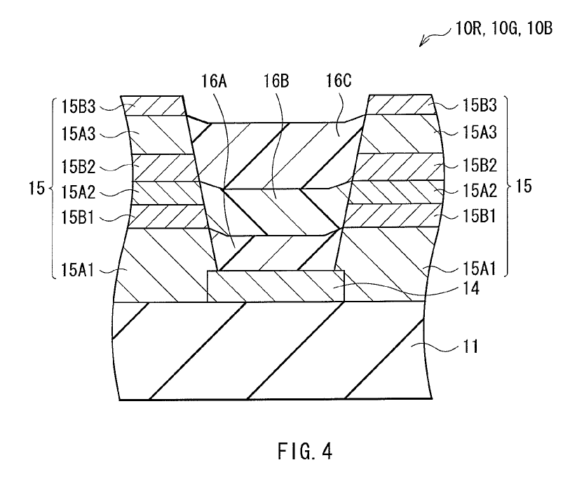

FIG. 4 illustrates a detailed cross sectional structure of the dividing wall 15 of this embodiment together with the substrate 11, the lower electrode 14, and the organic layer 16 described below (a hole injection layer 16A, a hole transport layer 16B, and the light emitting layer 16C). The dividing wall 15 is composed of a laminated structure having two or more types of inorganic material films having different wet characteristics. In this case, as an example, the dividing wall 15 is composed of a laminated structure having two types of inorganic material films that are a film having relatively high wet characteristics (lyophilic film) and a film having relatively low wet characteristics (liquid repellent film). Specifically, in the laminated structure of the dividing wall 15, lyophilic films (lyophilic films 15A1, 15A2, and 15A3) and liquid repellent films (liquid repellent films 15B1, 15B2, and 15B3) are alternately layered. More specifically, the lyophilic film 15A1, the liquid repellent film 15B1, the lyophilic film 15A2, the liquid repellent film 15B2, the lyophilic film 15A3, and the liquid repellent film 15B3 are layered in this order from the substrate 11 side. That is, in the laminated structure, the lowermost layer is the lyophilic film (the lyophilic film 15A1), and the uppermost layer is the liquid repellent film (the liquid repellent film 15B3).

Further, the hole injection layer 16A as the lowermost layer in the organic layer 16 has a thickness approximately equivalent to (preferably equal to) that of the lyophilic film (the lyophilic film 15A1) as the lowermost layer. The hole transport layer 16B and the light emitting layer 16C as the second or later organic layers in the organic layer 16 respectively have a thickness approximately equivalent to (preferably equal to) that of each entire laminated film composed of each liquid repellent film on the lower layer side and each lyophilic film on the upper layer side. Specifically, the hole transport layer 16B has a thickness approximately equivalent to that of the entire laminated film composed of the liquid repellent film 15B1 and the lyophilic film 15A2. The light emitting layer 16C has a thickness approximately equivalent to that of the entire laminated film composed of the liquid repellent film 15B2 and the lyophilic film 15A3. Each film thickness of the lyophilic films 15A1, 15A2, and 15A3 and the liquid repellent film 15B1, 15B2, and 15B3 is, for example, about from 5 nm to 150 nm both inclusive.

As known by Lotus effect in general, wet characteristics and surface roughness have relationship with each other. Thus, in the lyophilic films 15A1, 15A2, and 15A3, the film density is relatively high (dense film), and the contact angle is relatively low. Meanwhile, in the liquid repellent film 15B1, 15B2, and 15B3, the film density is relatively low (rough film) and the contact angle is relatively high. Therefore, by adopting different film formation conditions (film densities) as described later, the lyophilic films 15A1, 15A2, and 15A3 and the liquid repellent films 15B1, 15B2, and 15B3 are respectively able to be formed sequentially in the same (single) step (manufacturing facility).

Examples of an organic material used for the lyophilic films 15A1, 15A2, and 15A3 and the liquid repellent films 15B1, 15B2, and 15B3 include silicon oxide (SiOₓ), silicon nitride (SiNₓ), silicon oxynitride (SiNₓO_{y}), titanium oxide (TiOₓ), and aluminum oxide (AlₓO_{y}).

### (Organic Layer 16)

The organic layer 16 of the red organic EL device 1OR has, for example, a structure in which a hole injection layer 16AR, a hole transport layer 16BR, a red light emitting layer 16CR, an electron transport layer 16E, and an electron injection layer 16F are layered sequentially from the lower electrode 14 side. The organic layer 16 of the green organic EL device 10G has, for example, a structure in which a hole injection layer 16AG, a hole transport layer 16BG, a green light emitting layer 16CG, the electron transport layer 16E, and the electron injection layer 16F are layered sequentially from the lower electrode 14 side. The organic layer 16 of the blue organic EL device 10B has, for example, a structure in which a hole injection layer 16AB, a hole transport layer 16BB, a blue light emitting layer 16CB, the electron transport layer 16E, and the electron injection layer 16F are layered sequentially from the lower electrode 14 side. Of the foregoing layers, the electron transport layer 16E and the electron injection layer 16F are provided as a common layer for the red organic EL device 10R, the green organic EL device 10G, and the blue organic EL device 10B. Meanwhile, the hole injection layer 16A, the hole transport layer 16B, and the light emitting layer 16C described above are respectively and individually provided for the red organic EL device 10R, the green organic EL device 10G, and the blue organic EL device 10B (for each pixel).

### (Hole Injection Layer 16A)

The hole injection layers 16AR, 16AG, and 16AB are intended to improve efficiency of electron hole injection to each light emitting layer 16C (the red light emitting layer 16CR, the green light emitting layer 16CG, and the blue light emitting layer 16CB), and are buffer layers to prevent leakage. The hole injection layers 16AR, 16AG, and 16AB are provided on the lower electrode 14 respectively for the red organic EL device 10R, the green organic EL device 10G, and the blue organic EL device 10B.

The hole injection layers 16AR, 16AG, and 16AB preferably have, for example, a thickness from 5 nm to 100 nm both inclusive, and more preferably have a thickness from 8 nm to 50 nm both inclusive. The component material of the hole injection layers 16AR, 16AG, and 16AB may be selected as appropriate based on relation with a material of an electrode and a layer adjacent thereto. Examples thereof include polyaniline, polythiophene, polypyrrole, polyphenylene vinylene, polythienylene vinylene, polyquinoline, polyquinoxaline, and a derivative thereof, a conductive polymer such as a polymer including an aromatic amine structure in a main chain or a side chain, metal phthalocyanine (copper phthalocyanine or the like), and carbon.

In the case where the material used for the hole injection layers 16AR, 16AG, and 16AB is a polymer material, the weight average molecular weight (Mw) of the polymer material is preferably about from 10000 to 300000 both inclusive, in particular, the weight average molecular weight (Mw) of the polymer material is preferably about from 5000 to 200000 both inclusive. Further, an oligomer with the weight average molecular weight (Mw) in the range about from 2000 to 10000 both inclusive may be used. However, if Mw is less than 5000, there is a possibility that the hole injection layer is dissolved in forming layers on and after the hole transport layer. Further, if Mw exceeds 300000, there is a possibility that the material is gelated and film formation becomes difficult. The weight average molecular weight (Mw) is a value of a weight-average molecular weight in terms of polystyrene obtained by Gel Permeation Chromatography (GPC) by using tetrahydrofuran as a solvent.

Examples of typical conductive polymers used as the component material of the hole injection layers 16AR, 16AG, and 16AB include polyaniline, oligoaniline, and polydioxythiophene such as poly(3,4-ethylenedioxythiophene) (PEDOT). In addition, examples thereof include a polymer commercially available under the name of Nafion (trademark) made by H. C. starck, a polymer commercially available under the name of Liquion (trademark) in a dissolved state, El source (trademark) made by Nissan Chemical Industries, Ltd., and Berazol (trademark) as a conductive polymer made by Soken Chemical&Engineering Co., Ltd.

### (Hole Transport Layer 16B)

The hole transport layers 16BR, 16BG, and 16BB are respectively intended to improve efficiency to transport electron holes into the red light emitting layer 16CR, the green light emitting layer 16CG, and the blue light emitting layer 16CB. The hole transport layers 16BR, 16BG, and 16BB are provided on the hole injection layers 16AR, 16AG, and 16AB respectively for the red organic EL device 10R, the green organic EL device 10G, and the blue organic EL device 10B.

The hole transport layers 16BR, 16BG, and 16BB preferably have, for example, a thickness from 10 nm to 200 nm both inclusive, and more preferably have a thickness from 15 nm to 150 nm both inclusive though the thickness depends on the whole structure of the device. As a polymer material composing the hole transport layers 16BR, 16BG, and 16BB, a light emitting material dissolvable into an organic solvent such as polyvinyl carbazole, polyfluorene, polyaniline, polysilane, a derivative thereof, a polysiloxane derivative having an aromatic amine structure in a side chain or a main chain, polythiophene and a derivative thereof, polypyrrole or the like is able to be used.

In the case where a material used for the hole transport layers 16BR, 16BG, and 16BB is a polymer material, the weight average molecular weight (Mw) of the polymer material is preferably from 50000 to 300000 both inclusive, and in particular, is preferably from 100000 to 200000 both inclusive. If Mw is less than 50000, there is a possibility that in forming the light emitting layer 16C, a low molecular component in the polymer material is dropped, and a dot is generated in the hole injection layer 16A and the hole transport layer 16B, and thus initial performance of the organic EL device may be lowered and the device may be deteriorated. Meanwhile, if Mw exceeds 300000, there is a possibility that the material is gelated and film formation becomes difficult.

### (Light Emitting Layer 16C)

The red light emitting layer 16CR, the green light emitting layer 16CG, and the blue light emitting layer 16CB are intended to generate light due to electron-hole recombination by applying an electric field. The red light emitting layer 16CR, the green light emitting layer 16CG, and the blue light emitting layer 16CB preferably have, for example, a thickness from 10 nm to 200 nm both inclusive, and more preferably have a thickness from 15 nm to 150 nm both inclusive though the thickness depends on the whole structure of the device. The red light emitting layer 16CR, the green light emitting layer 16CG, and the blue light emitting layer 16CB are made of a mixed material in which a low molecular material is added to a polymer (light emitting) material. The low molecular material is preferably a monomer or an oligomer in which two to ten monomers are bonded having a weight average molecular weight of 50000 or less. A low molecular material having a weight average molecular weight exceeding the foregoing range is not necessarily excluded.

Though a description will be given in detail later, the red light emitting layer 16CR, the green light emitting layer 16CG, and the blue light emitting layer 16CB are formed by coating method such as inkjet method. At this time, the polymer material and the low molecular material are dissolved in at least one of the organic solvents such as toluene, xylene, anisole, cyclohexane, mesitylene (1,3,5-torimethyl benzene), pseudocumene (1,2,4-torimethyl benzene), dihydrobenzofuran, 1,2,3,4-tetramethyl benzene, tetralin, cyclohexyl benzene, 1-methylnaphthalene, p-anisyl alcohol, dimethyl naphthalene, 3-methylbiphenyl, 4-methylbiphenyl, 3-isopropylbiphenyl, and monoisopropyl naphthalene, and the resultant mixed solution is used to form the red light emitting layer 16CR, the green light emitting layer 16CG, and the blue light emitting layer 16CB.

Examples of polymer materials composing the red light emitting layer 16CR, the green light emitting layer 16CG, and the blue light emitting layer 16CB include the following materials. That is, a polyfluorene polymer derivative, a (poly)paraphenylenevinylene derivative, a polyphenylene derivative, a polyvinyl carbazole derivative, a polythiophene derivative, perylene pigment, coumarin pigment, rhodamine pigment, and a material obtained by doping an organic EL material into the foregoing polymer. As a doping material, rubrene, perylene, 9,10 diphenyl anthracene, tetraphenyl butadiene, nile red, coumarin 6 or the like is able to be used. For the blue light emitting layer 16CB, an anthracene derivative is able to be used as a host material, and a low molecular fluorescent material, a mineral phosphate pigment, a metal complex or the like is able to be used as a doping material. A specific doping material of the blue light emitting layer 16CB is a compound having the peak of the light emitting wavelength range about from 400 nm to 490 nm both inclusive. An organic material such as a naphthalene derivative, an anthracene derivative, a naphthacene derivative, a styryl amine derivative, and a bis(azinyl)methene boron complex is used. Specially, the organic material is preferably selected from the group consisting of an aminonaphthalene derivative, an aminoanthracene derivative, an aminochrysene derivative, an aminopyrene derivative, a styryl amine derivative, and a bis(azinyl)methene boron complex.

Further, a low molecular material is preferably added to the polymer material composing the red light emitting layer 16CR and the green light emitting layer 16CG. Thereby, injection efficiency of hole and electrons from the blue light emitting layer 16CB as the common layer to the red light emitting layer 16CR or the green light emitting layer 16CG is improved.

Specific examples of the low molecular material include benzine, styrilamine, triphenylamine, porphyrin, triphenylene, azatriphenylene, tetracyanoquinodimethane, triazole, imidazole, oxadiazole, polyarylalkane, phenylenediamine, arylamine, oxazole, anthracene, fluorenone, hydrazone, stilbene, a derivative thereof, and a heterocyclic conjugated monomer/oligomer such as a polysilane compound, a vinyl carbazole compound, a thiophene compound, and an aniline compound.

Further, specific examples of materials include α-naphtylphenylphenylenediamine, porphyrin, metal tetraphenylporphyrin, metal naphthalocyanine, hexacyanoazatriphenylene, 7,7,8,8-tetracyanoquinodimethane (TCNQ), 7,7,8,8-tetracyano-2,3,5,6-tetrafluoroquinodimethane (F4-TCNQ), tetracyano 4,4,4-tris(3_methylphenylphenylamino)triphenylamine, N,N,N′-tetrakis(p-tolyl)p-phenylenediamine, N,N,N′,N′-tetraphenyl-4,4′-diaminobiphenyl, N-phenylcarbazole, 4-di-p-tolylaminostylbene, poly(paraphenylenevinylene), poly(thiophenevinylene), and poly(2,2′-thienylpyrrol). However, the material is not limited thereto.

### (Electron Transport Layer 16E)

The electron transport layer 16E is intended to improve efficiency to transport electrons into the red light emitting layer 16CR, the green light emitting layer 16CG, and the blue light emitting layer 16CB. The electron transport layer 16E is provided on the whole area of these light emitting layers as a common layer. Examples of material of the electron transport layer 16E include quinoline, perylene, phenanthroline, bisstyril, pyradine, triazole, oxazole, fullerene, oxadiazole, and fluorenone or a derivative and a metal complex thereof Specific examples thereof include tris(8-hydoxyquinoline)aluminum (abbreviated to Alq3), anthracene, naphthalene, phenanthrene, pyrene, anthracene, perylene, butadiene, coumarin, C60, acridine, stilbene, 1,10-phenanthroline, and a derivative/a metal complex thereof

### (Electron Injection Layer 16F)

The electron injection layer 16F is intended to improve efficiency to inject electrons. The electron injection layer 16F is provided on the whole area of the electron transport layer 16E as a common layer. As the material of the electron injection layer 16F include lithium oxide (Li₂O) as an oxide of lithium (Li), cesium carbonate (Cs₂CO₃) as a composite oxide of cesium (Cs), and a mixture of the oxide/the composite oxide are able to be used. Further, the material of the electron injection layer 16F is not limited to the foregoing material. For example, an alkali earth metal such as calcium (Ca) and barium (Ba), an alkali metal such as lithium and cesium, a metal with small work function such as indium (In) and magnesium (Mg), an oxide/a composite oxide/a fluoride of these metals as a simple body or a mixture/an alloy of the metal/the oxide/the composite oxide/the fluoride may be used by improving stability.

### (Upper Electrode 17)

The upper electrode 17 has a thickness of, for example, from 2 nm to 200 nm both inclusive, and is made of a metal conductive film. Specific examples thereof include an alloy of Al, Mg, Ca, or Na. Specially, an alloy of magnesium and silver (Mg—Ag alloy) is preferable, since the Mg—Ag alloy has both electric conductivity and small absorption in a thin film. Though the ratio of magnesium and silver in the Mg—Ag alloy is not particularly limited, the film thickness ratio of Mg:Ag is desirably in the range from 20:1 to 1:1. Further, the material of the upper electrode 17 may be an alloy of Al and Li (Al—Li alloy).

Further, the upper electrode 17 may be a mixed layer containing an organic light emitting material such as an aluminum quinoline complex, a styrylamine derivative, and a phthalocyanine derivative. In this case, the upper electrode 17 may further separately have a layer having light transmittance such as MgAg as the third layer. In the case of active matrix drive system, the upper electrode 17 is formed as a film in a solid state over the substrate 11 in a state of being insulated from the lower electrode 14 by the organic layer 16 and the dividing wall 15, and is used as a common electrode for the red organic EL device 10R, the green organic EL device 10G, and the blue organic EL device 10B.

### (Protective Layer 20)

The protective layer 20 has a thickness of, for example, from 2 μm to 3 μm both inclusive, and may be made of one of an insulating material and a conductive material. Preferable examples of the insulating material include an inorganic amorphous insulating material such as amorphous silicon (a-Si), amorphous silicon carbide (a-SiC), amorphous silicon nitride (a-Si₁₋ₓNₓ), and amorphous carbon (a-C). Such an inorganic amorphous insulating material does not structure grains. Thus, a favorable protective film with low water permeability is able to be obtained.

### (Sealing Substrate 40)

The sealing substrate 40 is located on the upper electrode 17 side of the red organic EL device 10R, the green organic EL device 10G, and the blue organic EL device 10B. The sealing substrate 40 seals the red organic EL device 10R, the green organic EL device 10G, and the blue organic EL device 10B together with the adhesive layer (not illustrated). The sealing substrate 40 is made of a material such as glass transparent to light generated in the red organic EL device 10R, the green organic EL device 10G, and the blue organic EL device 10B. The sealing substrate 40 is, for example, provided with a color filter and a light shielding film as a black matrix (not illustrated), which extracts the light generated in the red organic EL device 10R, the green organic EL device 10G, and the blue organic EL device 10B, and absorbs outside light reflected by the red organic EL device 10R, the green organic EL device 10G, and the blue organic EL device 10B and the wiring therebetween to improve contrast.

The color filter has a red filter, a green filter, and a blue filter (not illustrated), which are sequentially arranged correspondingly to the red organic EL device 10R, the green organic EL device 10G, and the blue organic EL device 10B. The red filter, the green filter, and the blue filter are respectively formed in the shape of, for example, a rectangle without space therebetween. The red filter, the green filter, and the blue filter are respectively made of a resin mixed with a pigment. Adjustment is made by selecting a pigment so that light transmittance in the intended red, green, or blue wavelength region is high, and light transmittance in the other wavelength regions is low.

The light shielding film is composed of a black resin film having an optical density of 1 or more in which a black colorant is mixed or a thin film filter by using thin film interference. Of the foregoing, the light shielding film is preferably composed of the black resin film, since thereby the film is able to be formed inexpensively and easily. The thin film filter is obtained by layering one or more thin films composed of a metal, a metal nitride, or a metal oxide, and is intended to attenuate light by using thin film interference. Specific examples of the thin film filter include a filter in which chromium and chromium oxide (III)(Cr₂O₃) are alternately layered.

### [Manufacturing Method of Organic EL Display Unit]

The organic EL display unit 1 is able to be manufactured, for example, as follows.

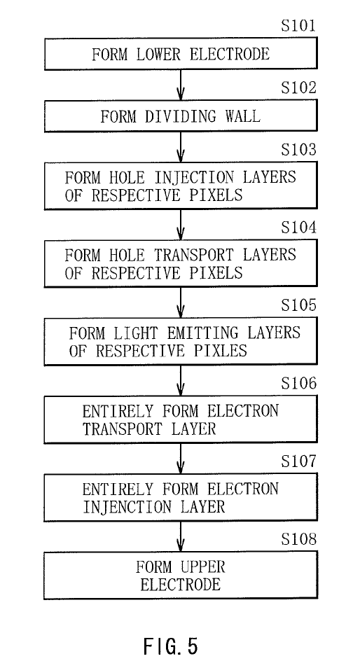

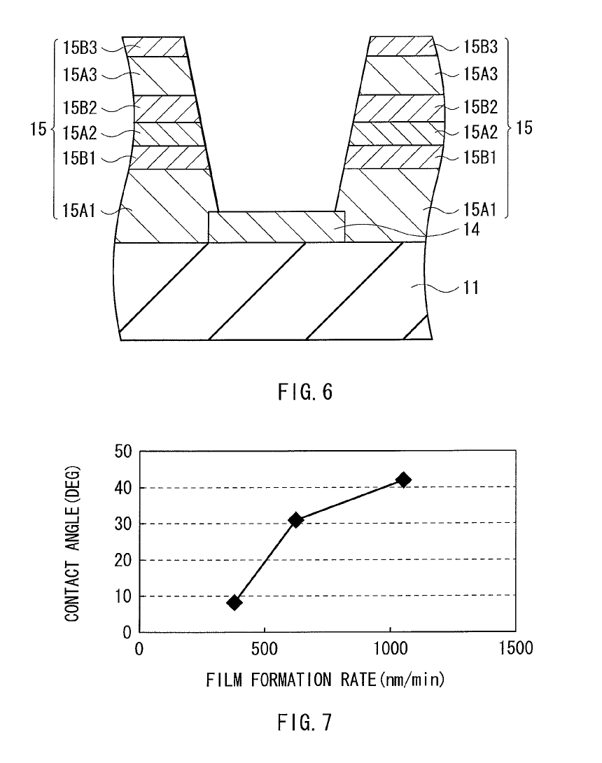

FIG. 5 illustrates a flow of a manufacturing method of the organic EL display unit 1. FIG. 6 to FIG. 10 illustrate the manufacturing method illustrated in FIG. 5 in order of steps. First, the pixel drive circuit 140 including the drive transistor Tr1 is formed on the substrate 11 made of the foregoing material, and a planarizing insulating film (not illustrated) made of, for example, a photosensitive resin is provided.

### (Step of Forming the Lower Electrode 14)

Next, a transparent conductive film made of, for example, ITO is formed on the whole area of the substrate 11. The transparent conductive film is patterned and thereby forming the lower electrode 14 respectively for the red organic EL device 10R, the green organic EL device 10G, and the blue organic EL device 10B (step S101). At this time, the lower electrode 14 is conducted to a drain electrode of the drive transistor Tr1 through a contact hole (not illustrated) of the planarizing insulating film (not illustrated).

### (Step of Forming the Dividing Wall 15)

Subsequently, an inorganic insulating material such as SiO₂ is deposited on the lower electrode 14 and the planarizing insulating film (not illustrated) by, for example, CVD (Chemical Vapor Deposition) method. However, film formation method at this time is not limited to the foregoing CVD method. For example, Physical Vapor Deposition (PVD) method, Atomic Layer Deposition (ALD) method, (vacuum) evaporation method or the like may be used. Next, the inorganic material is patterned in the shape to surround the light emitting region of the pixel by using photolithography technology and etching (wet etching or dry etching) technology, and thereby forming the dividing wall 15 illustrated in FIG. 6 (step S102).

At this time, for example, as illustrated in FIG. 7, by adopting different film formation conditions (film formation rate and film density) in forming the dividing wall 15, a plurality types of (in this case, two types of) inorganic material films having different contact angles (wet characteristics) are formed accordingly. Thereby, the lyophilic films 15A1, 15A2, and 15A3 and the liquid repellent films 15B1, 15B2, and 15B3 described above are respectively able to be formed sequentially in the same (single) step (manufacturing facility). Specifically, as the film formation rate (film density) is set lower, the contact angle of the inorganic material film is decreased (wet characteristics are increased). Meanwhile, as the film formation rate (film density) is set higher, the contact angle of the inorganic material film is increased (wet characteristics are decreased). That is, in this case, in forming the lyophilic films 15A1, 15A2, and 15A3, the film formation rate (film density) is set low relatively, and the contact angle is relatively small. Meanwhile, in forming the liquid repellent films 15B1, 15B2, and 15B3, the film formation rate (film density) is set high relatively, and the contact angle is relatively large.

### (Step of Forming the Hole Injection Layer 16A)

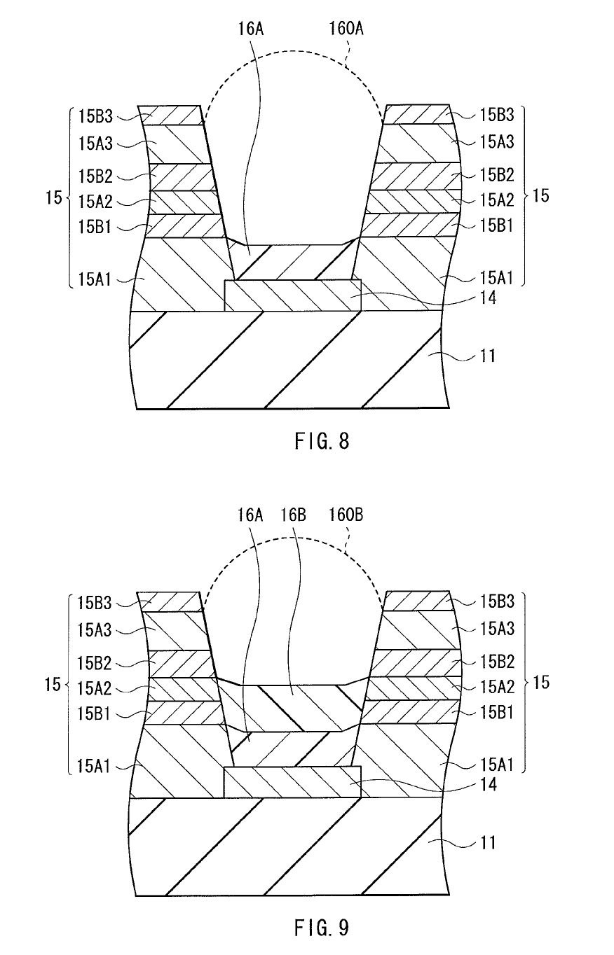

Next, as illustrated in FIG. 8, the hole injection layer 16A (the hole injection layers 16AR, 16AG, and 16AB) of each pixel made of the foregoing material is formed in the region surrounded by the dividing wall 15 (step S103). The hole injection layers 16AR, 16AG, and 16AB are formed by coating method (wet method) such as spin coating method and droplet discharge method. In particular, since the formation material of the hole injection layers 16AR, 16AG, and 16AB should be selectively arranged in the region surrounded by the upper dividing wall 15, inkjet method or nozzle coating method as a droplet discharge method is preferably used.

Specifically, for example, by ink jet method, a solution or dispersion liquid of polyaniline, polythiophene or the like as the formation material of the hole injection layers 16AR, 16AG, and 16AB is arranged on the exposed face of the lower electrode 14. After that, by providing heat treatment (dry treatment), the hole injection layers 16AR, 16AG, and 16AB of the respective pixels are formed. An organic material solution 160A indicated by a dashed line in FIG. 8 illustrates a state before heat treatment of a hole injection layer solution that is discharged from, for example, an ink jet head and is filled into (is landed in) the region surrounded by the dividing wall 15.

At this time, filling position accuracy of the organic material solution 160A (hole injection layer solution) is secured, and short circuit with the upper electrode 17 due to wet on the side face of the dividing wall 15, inter-pixel leakage and the like are decreased by the film with relatively low wet characteristics (the liquid repellent film 15B1). Further, in the heat treatment (drying step), the organic material solution 160A is prevented from being repelled, and variation of the film thickness of the hole injection layer 16A is decreased by the film with relatively high wet characteristics (the lyophilic film 15A1).

In the foregoing heat treatment, a solvent or a dispersion medium is dried and is subsequently heated at high temperature. In the case where a conductive polymer such as polyaniline and polythiophene is used, air atmosphere or oxygen atmosphere is preferable, since the conductive polymer is oxidized by oxygen and thereby conductivity is easily expressed.

Heating temperature is preferably from 150 deg C. to 300 deg C. both inclusive, and is more preferably from 180 deg C. to 250 deg C. both inclusive. Time is preferably about from 5 minutes to 300 minutes both inclusive, and is more preferably from 10 minutes to 240 minutes both inclusive though time depends on temperature and atmosphere. The film thickness after drying is preferably from 5 nm to 100 nm both inclusive, and is more preferably from 8 nm to 50 nm both inclusive.

### (Step of Forming the Hole Transport Layer 16B)

Next, as illustrated in FIG. 9, the hole transport layer 16B (the hole transport layers 16BR, 16BG, and 16BB) of the respective pixels made of the foregoing material are formed on the hole injection layer 16A (the hole injection layers 16AR, 16AG, and 16AB) (step S104). The hole transport layers 16BR, 16BG, and 16BB are formed by coating method (wet method) such as spin coating method and droplet discharge method. In particular, since the formation material of the hole transport layers 16BR, 16BG, and 16BB should be selectively arranged in the region surrounded by the dividing wall 15, inkjet method or nozzle coating method as a droplet discharge method is preferably used.

Specifically, for example, by ink jet method, a solution or dispersion liquid of a polymer as the formation material of the hole transport layers 16BR, 16BG, and 16BB is arranged on the exposed face of the hole injection layers 16AR, 16AG, and 16AB. After that, by providing heat treatment (drying treatment), the hole transport layers 16BR, 16BG, and 16BB of the respective pixels are formed. An organic material solution 160B illustrated by a dashed line in FIG. 9 illustrates a state before heat treatment of a hole injection layer solution that is discharged from, for example, an ink jet head and is filled into (is landed in) the region surrounded by the dividing wall 15.

At this time, as in the case of the foregoing hole injection layer 16A, filling position accuracy of the organic material solution 160B (hole transport layer solution) is secured, and short circuit with the upper electrode 17 due to wet on the side face of the dividing wall 15, inter-pixel leakage and the like are decreased by the film with relatively low wet characteristics (the liquid repellent film 15B2). Further, in the heat treatment (drying step), the organic material solution 160B is prevented from being repelled, and variation of the film thickness of the hole injection layer 16B is decreased by the film with relatively high wet characteristics (the lyophilic film 15A2).

In the foregoing heat treatment, a solvent or a dispersion medium is dried and heated at high temperature. As atmosphere in which coating is provided and an atmosphere in which the solvent is dried and heated, atmosphere having a main component of nitrogen (N₂) is preferable. If oxygen and moisture exist, there is a possibility that light emitting efficiency and life of the formed organic EL display unit are lowered. In particular, in the heating step, influence of oxygen and moisture is large, to which attention should be paid. The oxygen concentration is preferably from 0.1 ppm to 100 ppm both inclusive, and is more preferably 50 ppm or less. In the case where oxygen with a concentration larger than 100 ppm exists, the interface of the formed thin film is contaminated, and thereby there is a possibility that light emitting efficiency and life of the obtained organic EL display unit are lowered. Further, in the case where oxygen with a concentration smaller than 0.1 ppm exists, though device characteristics are not damaged, cost for an apparatus for keeping the concentration of atmosphere smaller than 0.1 ppm may be extremely large in the current mass production process.

Further, regarding moisture, for example, the dew point is preferably from −80 deg C. to −40 deg C. both inclusive, is more preferably −50 deg C. or less, and is much more preferably −60 deg C. or less. In the case where moisture having a dew point higher than −40 deg C. exists, there is a possibility that the interface of the formed thin film is contaminated, and light emitting efficiency and life of the obtained organic EL display unit are lowered. Further, in the case where moisture having a dew point lower than −80 deg C. exists, though device characteristics are not damaged, cost for an apparatus for keeping the dew point lower than −80 deg C. may be extremely large in the current mass production process.

Heating temperature is preferably from 100 deg C. to 230 deg C. both inclusive, and is more preferably from 100 deg C. to 200 deg C. both inclusive. Heating temperature is preferably at least lower than the temperature at which the hole injection layers 16AR, 16AG, and 16AB are formed. Time is preferably about from 5 minutes to 300 minutes both inclusive, and is more preferably from 10 minutes to 240 minutes both inclusive though time depends on temperature and atmosphere. The film thickness after drying is preferably from 10 nm to 200 nm both inclusive, and is more preferably from 15 nm to 150 nm both inclusive though the film thickness depends on the whole structure of the device.

### (Step of Forming the Light Emitting Layer 16C)

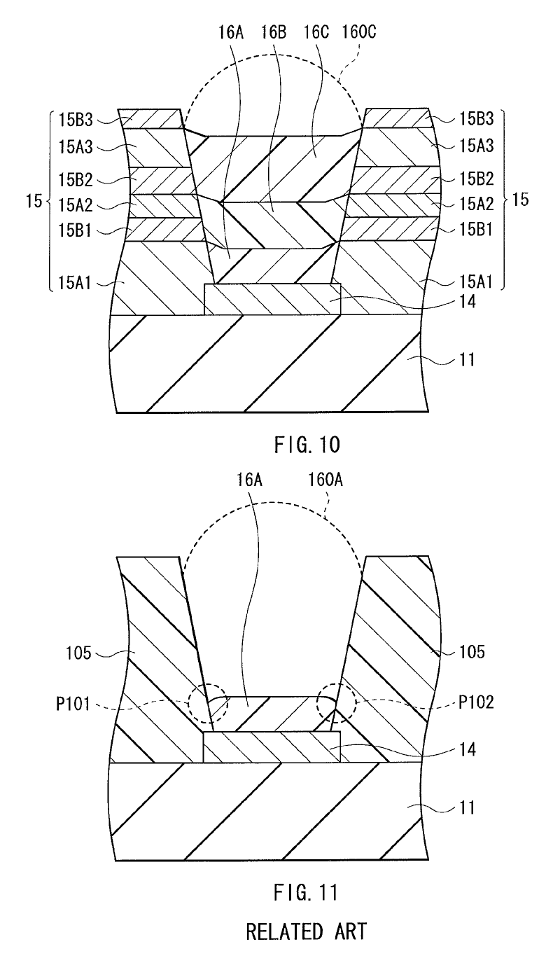

Subsequently, as illustrated in FIG. 10, the red light emitting layer 16CR made of the foregoing material is formed on the hole transport layer 16BR of the red organic EL device 10R. Further, the green light emitting layer 16CG made of the foregoing material is formed on the hole transport layer 16BG of the green organic EL device 10G. Further, the blue light emitting layer 16CB made of the foregoing material is formed on the hole transport layer 16BB of the blue organic EL device 10B (step S105). The red light emitting layer 16CR, the green light emitting layer 16CG, and the blue light emitting layer 16CB are formed by coating method (wet method) such as spin coating method and droplet discharge method. In particular, since the formation material of the red light emitting layer 16CR, the green light emitting layer 16CG, and the blue light emitting layer 16CB should be selectively arranged in the region surrounded by the dividing wall 15, inkjet method or nozzle coating method as a droplet discharge method is preferably used.

Specifically, for example, by inkjet method, a mixed solution or dispersion liquid obtained by dissolving a polymer material and a low molecular material as a formation material of the red light emitting layer 16CR, the green light emitting layer 16CG, and the blue light emitting layer 16CB in a mixed solvent of xylene and cyclohexyl benzene at a rate of 2:8 so that the polymer material and the low molecular material becomes, for example, 1 wt % is arranged on the exposed face of the hole transport layers 16BR, 16BG, and 16BB. After that, by providing heat treatment based on a method and conditions similar to those of the heat treatment (drying treatment) described in the steps of forming the hole transport layers 16BR, 16BG, and 16BB, the red light emitting layer 16CR, the green light emitting layer 16CG, and the blue light emitting layer 16CB are formed. An organic material solution 160C indicated by a dashed line in FIG. 10 illustrates a state before heat treatment of a light emitting layer solution that is discharged from, for example, an ink jet head and is filled into (is landed in) the region surrounded by the dividing wall 15.

At this time, as in the case of the foregoing hole injection layer 16A and the foregoing hole injection layer 16B, filling position accuracy of the organic material solution 160C (light emitting layer solution) is secured, and short circuit with the upper electrode 17 due to wet on the side face of the dividing wall 15, inter-pixel leakage and the like are decreased by the film with relatively low wet characteristics (the liquid repellent film 15B3). Further, in the heat treatment (drying step), the organic material solution 160C is prevented from being repelled, and variation of the film thickness of the light emitting layer 16C is decreased by the film with relatively high wet characteristics (the lyophilic film 15A3).

### (Step of Forming the Electron Transport Layer 16E, the Electron Injection Layer 16F, and the Upper Electrode 17)

Next, as illustrated in FIG. 3, the electron transport layer 16E, the electron injection layer 16F, and the upper electrode 17 each made of the foregoing material are formed on the whole area of the light emitting layer 16C (the red light emitting layer 16CR, the green light emitting layer 16CG, and the blue light emitting layer 16CB) of the respective pixels by, for example, evaporation method (steps S106, S107, and S108).

After the upper electrode 17 is formed, as illustrated in FIG. 3, the protective layer 20 is formed by film forming method such as evaporation method and CVD method in which film formation particle energy is small to the degree at which little effect exists on the base. For example, in the case where the protective layer 20 composed of amorphous silicon nitride is formed, a film having a film thickness from 2 to 3 μm both inclusive is formed by CVD method. At this time, film forming temperature is desirably set to normal temperature to prevent luminance lowering due to deterioration of the organic layer 16, and film forming is desirably performed under conditions that the film stress is the minimum to prevent separation of the protective layer 20.

The electron transport layer 16E, the electron injection layer 16F, the upper electrode 17, and the protective layer 20 are entirely formed in a state of a solid film without using a mask. Further, the formation of the electron transport layer 16E, the electron injection layer 16F, the upper electrode 17, and the protective layer 20 is desirably performed continuously in the same film forming apparatus without being exposed in the air. Thereby, deterioration of the organic layer 16 due to moisture in the air is prevented.

In the case where an auxiliary electrode (not illustrated) is formed in the same step as that of the lower electrode 14, the organic layer 16 formed in a state of a solid film on the auxiliary electrode may be removed by a method such as laser ablation before forming the upper electrode 17. Thereby, the upper electrode 17 is able to be directly connected to the auxiliary electrode, and contact is improved.

After the protective film 20 is formed, for example, the light shielding film made of the foregoing material is formed on the sealing substrate 40 made of the foregoing material. Subsequently, the sealing substrate 40 is coated with a material of the red filter (not illustrated) by spin coating method or the like. The resultant is patterned by photolithography technology, burned, and thereby the red filter is formed. Subsequently, the blue filter (not illustrated) and the green filter (not illustrated) are sequentially formed in the same manner as in the red filter (not illustrated).

After that, the adhesive layer (not illustrated) is formed on the protective layer 20, and the sealing substrate 40 is bonded with the protective layer 20 with the adhesive layer in between. Accordingly, the organic EL display unit 1 illustrated in FIG. 1 to FIG. 4 is completed.

### [Action and Effect of Organic EL Display Unit]

In the organic EL display unit 1, the scanning signal is supplied to each pixel through the gate electrode of the writing transistor Tr2 from the scanning line drive circuit 130, and the image signal from the signal line drive circuit 120 is retained in the retentive capacity Cs through the writing transistor Tr2. That is, the drive transistor Tr1 is on/off controlled in response to the signal retained in the retentive capacity Cs, and thereby drive current Id is injected into the red organic EL device 10R, the green organic EL device 10G, and the blue organic EL device 10B, electron-hole recombination is generated, and thereby light is emitted. The light is transmitted thorough the lower electrode 14 and the substrate 11 in the case of bottom emission, and is transmitted through the upper electrode 17, the color filter (not illustrated), and the sealing substrate 40 in the case of top emission, and is extracted.

### COMPARATIVE EXAMPLE 1

FIG. 11 illustrates a cross sectional structure of a dividing wall (dividing wall 105) according to Comparative example 1 together with the substrate 11, the lower electrode 14, and the hole injection layer 16A, which corresponds to the state after forming the hole injection layer 16A. The dividing wall 105 of Comparative example 1 has a single layer structure composed of an organic material film. Specifically, the dividing wall 105 is made of, for example, a liquid repellent resin such as a fluorine resin or a resin with the surface fluorinated by CF₄ plasma treatment or the like, and shows liquid repellent characteristics. Filling position accuracy of the solution (organic material solution 160A) of the organic layer such as the hole injection layer 16A is secured, and short circuit with the upper electrode 17 due to wet on the side face of the dividing wall 105, inter-pixel leakage and the like are inhibited by the dividing wall 105 showing such liquid repellent characteristics.

However, in the single-layer-structured dividing wall 105 showing liquid repellent characteristics, for example, in the case where the organic material solution 160A is contacted with the dividing wall 105, the contact angle in a region in the vicinity of the contact section (outer circumferential section of the pixel region) is relatively high. In other words, the organic material solution 160A is repelled by the surface of the dividing wall 105 having high wet characteristics in heating treatment (drying step). In the result, as indicated in referential symbols P101 and P102 in FIG. 11, the film thickness of the organic layer (in this case, the hole injection layer 16A) of the organic layer in the outer circumferential section of the pixel region is drastically decreased, resulting in short circuit with the upper electrode 17 or defect and fault of the display unit due to film thickness variation.

### COMPARATIVE EXAMPLE 2

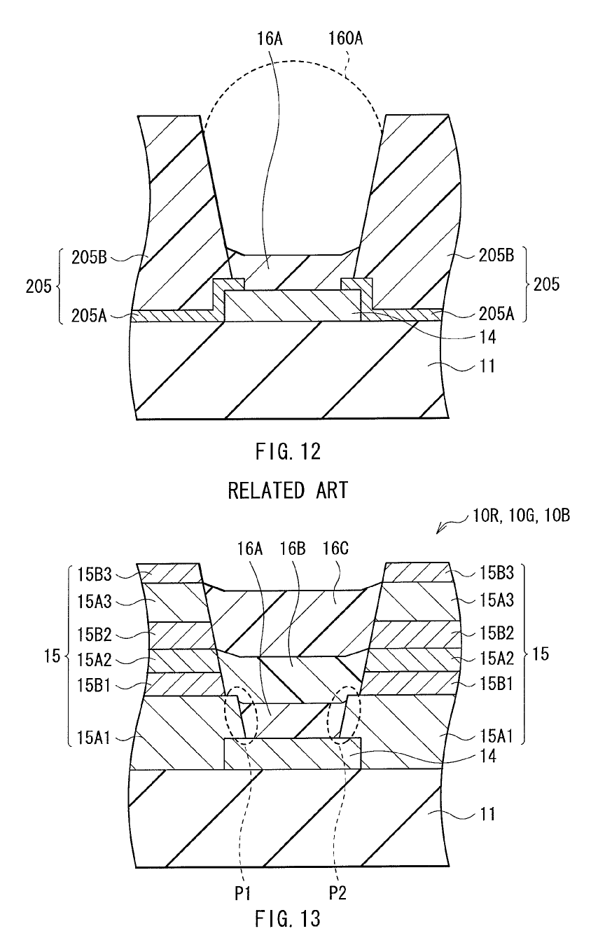

FIG. 12 illustrates a cross sectional structure of a dividing wall (dividing wall 205) according to Comparative example 2 together with the substrate 11, the lower electrode 14, and the hole injection layer 16A, which corresponds to the state after forming the hole injection layer 16A. The dividing wall 205 of Comparative example 2 has a structure different from that of the dividing wall 105 of Comparative example 1 described above, and has a two-layer structure composed of a dividing wall (first dividing wall) 205A made of an inorganic material showing lyophilic characteristics and a dividing wall (second dividing wall) 205B made of an organic material showing liquid repellency. Specifically, the dividing wall 205A showing lyophilic characteristics and the dividing wall 205B showing liquid repellency are layered in this order on the substrate 11.

In the dividing wall 205 having the two-layer structure, film thickness uniformity of the hole injection layer 16A is realized by the liquid repellent dividing wall 205A to prevent film thickness nonuniformity resulting from the fact that the organic material solution 160A is repelled by the liquid repellent dividing wall 205B as in Comparative example 1. Further, as in Comparative example 1, filling position accuracy of the solution (organic material solution 160A) of the organic layer such as the hole injection layer 16A is secured, and short circuit with the upper electrode 17 due to wet on the side face of the dividing wall 205B, inter-pixel leakage and the like are inhibited by the dividing wall 205B showing liquid repellent characteristics. Accordingly, in the dividing wall 205 of Comparative example 2, both film thickness uniformity of the organic layer and filling position accuracy of the organic material solution are achieved.

However, in the two-layer-structured dividing wall 205, the dividing wall 205A made of the inorganic material and the dividing wall 205B made of the organic material should be formed respectively in different steps, and thus manufacturing cost is high. In particular, in the case where the organic layer has a laminated structure composed of a plurality of layers (for example, the hole injection layer 16A, the hole transport layer 16B, and the light emitting layer 16C), the dividing walls 205A and 205B should be formed according to each film thickness of each layer. Thus, the number of steps is increased by just that much, which leads to further cost increase. Moreover, surface treatment is necessitated so that the dividing walls 205A and 205B respectively show lyophilic characteristics and liquid repellency, which also leads to increase of the number of steps.

### Present Embodiment

Meanwhile, in this embodiment, as illustrated in FIG. 4, the dividing wall 15 is composed of the laminated structure having two or more types (in this case, two types) of films with different wet characteristics. Thereby, in forming the organic layer 16 (the hole injection layer 16A, the hole transport layer 16B, and the light emitting layer 16C) in the pixel by using wet method (coating method), the following action and the following effect are able to be obtained. That is, first, filling position accuracy of the organic material solutions 160A, 160B, 160C and the like is secured, and short circuit with the upper electrode 17 due to wet on the side face of the dividing wall 15, inter-pixel leakage and the like are inhibited by the film with relatively low wet characteristics (the liquid repellent films 15B1, 15B2, and 15B3). Further, in the heat treatment (drying step), the organic material solutions 160A, 160B, 160C and the like are prevented from being repelled, and variation of the film thickness in the organic layer 16 is decreased by the film with relatively high wet characteristics (the lyophilic films 15A1, 15A2, and 15A3).

Further, two or more types (in this case, two types) of films with different wet characteristics are all made of an inorganic material film. Thus, differently from the foregoing Comparative example 2, the dividing wall composed of the laminated structure is able to be formed sequentially in a single (identical) step. Specifically, for example, as illustrated in FIG. 7, by adopting different film formation conditions (film formation rate and film density) in forming the dividing wall 15, a plurality of types of (in this case, two types of) inorganic material films having different contact angles (wet characteristics) are able to be formed accordingly. Thus, compared to the technique of the foregoing Comparative example 2, the number of steps in forming the dividing wall is able to be decreased. Further, even if the organic layer has a laminated structure composed of a plurality of layers (the hole injection layer 16A, the hole transport layer 16B, and the light emitting layer 16C), the dividing wall 15 having a laminated structure composed of three or more layers is able to be easily formed by sequentially changing the film formation conditions accordingly. Further, differently from the foregoing Comparative example 2, surface treatment is not necessitated in forming the lyophilic films 15A1, 15A2, and 15A3 and the liquid repellent films 15B1, 15B2, and 15B3, leading to decreasing the number of steps.

Accordingly, in this embodiment, the dividing wall 15 is composed of a laminated structure having two or more types of films having different wet characteristics. Thus, filling position accuracy of the organic material solution is able to be secured, inter-pixel short circuit is able to be decreased, film thickness uniformity of the organic layer is able to be improved, and display quality is able to be improved. Further, two or more types of films with different wet characteristics are all made of an inorganic material film. Thus, the dividing wall 15 composed of the laminated structure is able to be formed sequentially in a single step, and the number of steps is able to be decreased. Accordingly, while low cost is realized, display image is able to be improved.

### <Modifications>

Subsequently, a description will be given of modifications (first and second modifications) of the foregoing embodiment. For the same components as the components in the foregoing embodiment, the same referential symbols are affixed thereto, and the description thereof will be omitted as appropriate.

### [First Modification]

FIG. 13 illustrates a cross sectional structure of the dividing wall 15 according to the first modification together with the substrate 11, the lower electrode 14, the hole injection layer 16A, the hole transport layer 16B, and the light emitting layer 16C. The dividing wall 15 according to this modification has a structure similar to that of the dividing wall 15 of the foregoing embodiment, except that the lyophilic film (in this case, the lyophilic film 15A1) projects deeper in the internal direction (central direction) of the pixel than the liquid repellent films 15B1, 15B2, and 15B3.

Due to the foregoing structure, in this modification, for example, as illustrated in referential symbols P1 and P2 in the figure, film thickness uniformity in forming the organic layer (in this case, the hole injection layer 16A) is able to be further improved, and display quality is able to be further improved (variation of light emitting luminance in the pixel is able to be decreased).

In this case, the description has been given of the case that only the lyophilic film 15A1 out of the lyophilic films 15A1, 15A2, and 15A3 projects deeper. However, application is not limited to this case. That is, as long as at least one of the plurality of lyophilic films is formed to project deeper in the internal direction of the pixel than the liquid repellent films, effect similar to that of this modification is able to be obtained.

### [Second Modification]

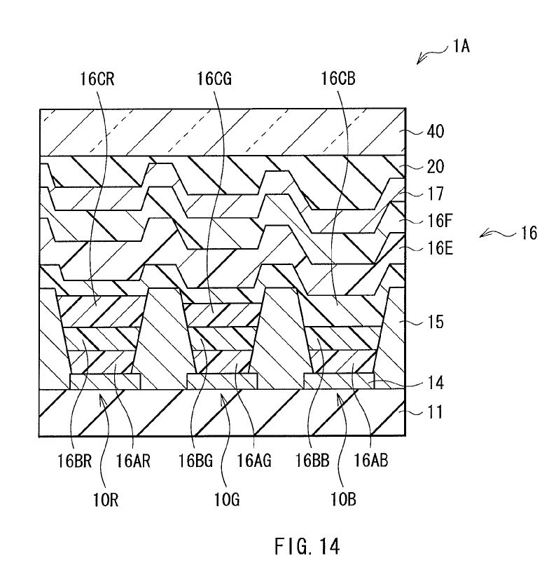

FIG. 14 illustrates a cross sectional structure of the display region 110 in an organic EL display unit (organic EL display unit 1A) according to the second modification. In the organic EL display unit 1 of the foregoing embodiment, the hole injection layer 16A, the hole transport layer 16B, and the light emitting layer 16C are respectively provided for each pixel. Meanwhile, in the organic EL display unit 1A of the modification, the blue light emitting layer 16CB is a layer common to each pixel. That is, the blue light emitting layer 16CB is provided entirely and commonly to the red organic EL device 10R, the green organic EL device 10G, and the blue organic EL device 10B.

In this modification, the hole transport layer 16BB may be a low molecular material (a monomer and an oligomer) or a polymer material. Of the low molecular materials used in this modification, the monomer is a substance that is other than a compound such as a polymer and a condensed body of a low molecular compound similar to the low molecular material added to the red light emitting layer 16CR and the green light emitting layer 16CG, that has a single molecular weight, and that exists as a single molecule. Further, the oligomer is a substance in which a plurality of monomers are bonded having a weight average molecular weight (Mw) of 50000 or less. Further, as the polymer material used for the hole transport layers 16BR and 16BG, it is enough that the weight average molecular weight of the polymer material is from 50000 to 300000 both inclusive, and is, in particular, preferably about from 100000 to 200000 both inclusive. As the low molecular material and the high molecular material used for the hole transport layer 16BB, two or more types of materials having different molecular weights and different weight average molecular weights may be used by mixture.

As the low molecular material used for the hole transport layer 16BB, benzine, styrilamine, triphenylamine, porphyrin, triphenylene, azatriphenylene, tetracyanoquinodimethane, triazole, imidazole, oxadiazole, polyarylalkane, phenylenediamine, arylamine, oxazole, anthracene, fluorenone, hydrazone, stilbene, a derivative thereof, and a heterocyclic conjugated monomer/oligomer/polymer such as a polysilane compound, a vinyl carbazole compound, a thiophene compound, and an aniline compound are able to be used.

The polymer material may be selected as appropriate in terms of a material of the electrode and a layer adjacent thereto. As the polymer material, a light emitting material soluble in an organic solvent such as polyvinyl carbazole, polyfluorene, polyaniline, polysilane, or a derivative thereof, a polysiloxane derivative having aromatic amine in a side chain or a main chain, a polythiophene and a derivative thereof, polypyrrole and the like are able to be used.

In the blue light emitting layer 16CB of this modification, a guest material of a blue or green fluorescent pigment is doped with the use of an anthracene as a host material. The blue light emitting layer 16CB generates blue or green emission light. As the luminescent guest material composing the blue light emitting layer 16CB, a material having high light emitting efficiency, for example, an organic light emitting material such as a low molecular fluorescent material, a phosphorescent pigment, and a metal complex is used.

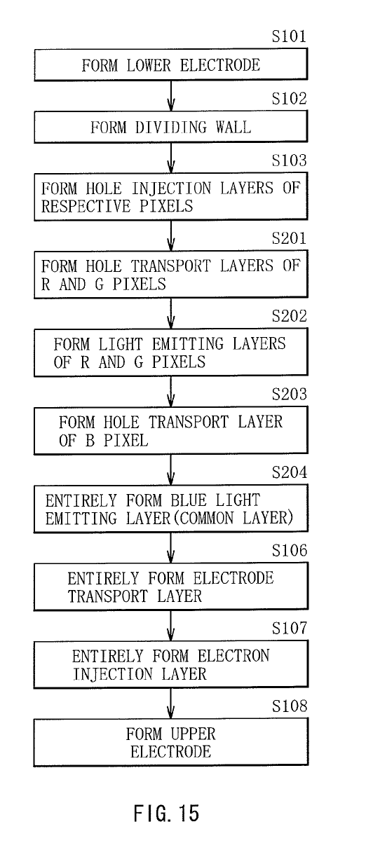

FIG. 15 illustrates a flow of a manufacturing method of the organic EL display unit 1A of this modification. Steps of the manufacturing method of the organic EL display unit 1A are similar to those of the manufacturing method of the organic EL display unit 1 illustrated in FIG. 5, except that steps S201 to S204 described below are provided instead of steps S104 and S105.

Specifically, after the hole injection layer 16A of each pixel is formed, first, the hole transport layers 16BR and 16BG of the red organic EL device 1OR and the green organic EL device 10G are selectively formed by a method similar to that of step S104 described above (step S201). Next, the light emitting layers 16CR and 16CG of the red organic EL device 10R and the green organic EL device 10G are selectively formed by a method similar to that of step S105 described above (step S202).

Subsequently, the hole transport layer 16BB made of the foregoing low molecular material is formed on the hole injection layer 16AB for the blue organic light emitting device 10B (step S203). The hole transport layer 16BB is formed by coating method such as spin coating method and droplet discharge method. In particular, since the formation material of the hole transport layer 16BB should be selectively arranged in the region surrounded by the dividing wall 15, inkjet method or nozzle coating method as a droplet discharge method is preferably used.

Specifically, for example, by ink jet method, a low molecular solution or a dispersion liquid as the formation material of the hole transport layer 16BB is arranged on the exposed face of the hole injection layer 16AB. After that, by providing heat treatment by a method similar to that of the heat treatment (drying treatment) described in the step of forming the hole transport layers 16BR and 16BG of the red organic EL device 10R and the green organic EL device 10G under conditions similar to those of the heat treatment (drying treatment) described in the step of forming the hole transport layers 16BR and 16BG of the red organic EL device 10R and the green organic EL device 10G, the hole transport layer 16BB is formed.

Next, the blue light emitting layer 16CB made of the foregoing low molecular material is formed as a common layer on the whole area of the hole transport layers 16BR, 16BG, and 16BB by, for example, evaporation method (step S204).

After that, in the same manner as that of the foregoing embodiment, steps S106 to S108 described above are performed. Thereby, the organic EL display unit 1A illustrated in FIG. 14 is completed.

In the organic EL display unit 1A of this modification having the foregoing configuration, by providing the dividing wall 15 similar to that of the foregoing embodiment, similar effect is able to be obtained by similar action. That is, while low cost is realized, display image is able to be improved.

### APPLICATION EXAMPLES

A description will be given of application examples of the organic EL display unit described in the foregoing embodiment and the modifications. The organic EL display unit of the foregoing embodiment and the like is applicable to an electronic device in any field such as a television device, a digital camera, a notebook personal computer, a portable terminal device such as a mobile phone, and a video camera. In other words, the organic EL display unit of the foregoing embodiment and the like is applicable to an electronic device in any field for displaying a picture signal inputted from outside or a picture signal generated inside as an image or a video.

### (Module)

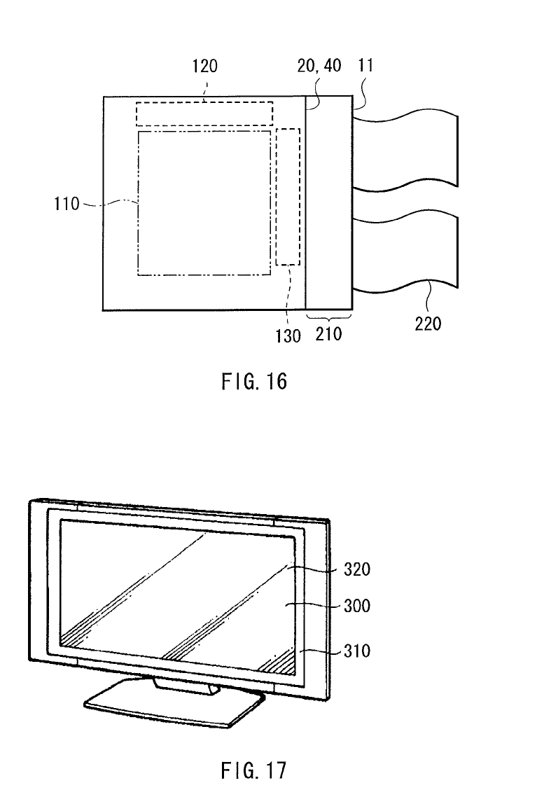

The organic EL display unit of the foregoing embodiment and the like is incorporated in various electronic devices such as after-mentioned first to fifth application examples as a module as illustrated in FIG. 16, for example. In the module, for example, a region 210 exposed from the protective layer 20 and the sealing substrate 40 is provided on a side of the substrate 11, and an external connection terminal (not illustrated) is formed in the exposed region 210 by extending the wirings of the signal line drive circuit 120 and the scanning line drive circuit 130. The external connection terminal may be provided with a Flexible Printed Circuit (FPC) 220 for inputting and outputting a signal.

### First Application Example

FIG. 17 is an appearance of a television device to which the organic EL display unit of the foregoing embodiment and the like is applied. The television device has, for example, a picture display screen section 300 including a front panel 310 and a filter glass 320. The picture display screen section 300 is composed of the organic EL display unit according to the foregoing embodiment and the like.

### Second Application Example

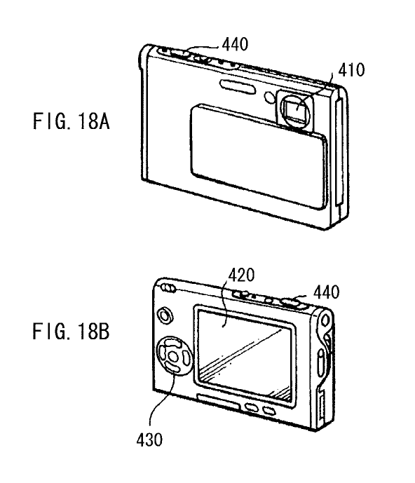

FIGS. 18A and 18B are an appearance of a digital camera to which the organic EL display unit of the foregoing embodiment and the like is applied. The digital camera has, for example, a light emitting section for a flash 410, a display section 420, a menu switch 430, and a shutter button 440. The display section 420 is composed of the organic EL display unit according to the foregoing embodiment and the like.

### Third Application Example

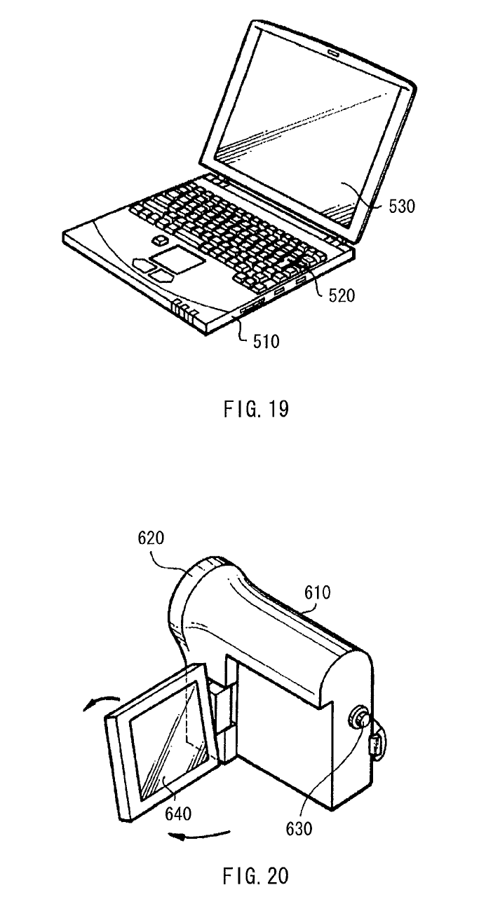

FIG. 19 is an appearance of a notebook personal computer to which the organic EL display unit of the foregoing embodiment and the like is applied. The notebook personal computer has, for example, a main body 510, a keyboard 520 for operation of inputting characters and the like, and a display section 530 for displaying an image. The display section 530 is composed of the organic EL display unit according to the foregoing embodiment and the like.

### Fourth Application Example

FIG. 20 is an appearance of a video camera to which the organic EL display unit of the foregoing embodiment and the like is applied. The video camera has, for example, a main body 610, a lens for shooting an object 620 provided on the front side face of the main body 610, a start/stop switch in shooting 630, and a display section 640. The display section 640 is composed of the organic EL display unit according to the foregoing embodiment and the like.

### Fifth Application Example

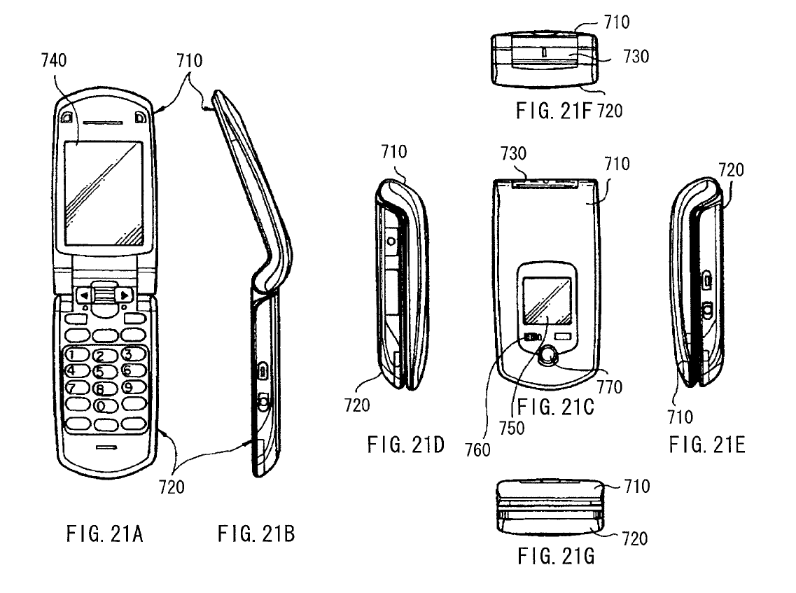

FIGS. 21A to 21G are an appearance of a mobile phone to which the organic EL display unit of the foregoing embodiment and the like is applied. In the mobile phone, for example, an upper package 710 and a lower package 720 are jointed by a joint section (hinge section) 730. The mobile phone has a display 740, a sub-display 750, a picture light 760, and a camera 770. The display 740 or the sub-display 750 is composed of the organic EL display unit according to the foregoing embodiment and the like.

### <Other Modifications>

While the present disclosure has been described with reference to the embodiment, the modifications, and the application examples, the present disclosure is not limited to the foregoing embodiment and the like, and various modifications may be made.

For example, the material, the thickness, the film-forming method, the film-forming conditions and the like of each layer are not limited to those described in the foregoing embodiment and the like, and other material, other thickness, other film-forming method, and other film-forming conditions may be adopted.

Further, in the foregoing embodiment and the like, the description has been given of a case that the dividing wall is composed of the laminated structure having two types of inorganic material films with different wet characteristics. However, the structure of the dividing wall is not limited thereto. The dividing wall may be composed of a laminated structure having three or more types of inorganic material films with different wet characteristics. Similarly, in the foregoing embodiment and the like, the description has been given of a case that in the laminated structure of the dividing wall, the lyophilic films and the liquid repellent films are alternately layered. However, the lyophilic films and the liquid repellent films are not necessarily alternately layered. Further, in the foregoing embodiment and the like, the description has been given of a case that in the laminated structure of the dividing wall, the lowermost layer is the lyophilic film, and the uppermost layer is the liquid repellent film. However, the structure is not limited thereto, and other laminated structure may be adopted.

Further, in the foregoing embodiment and the like, the description has been given of a case that the lowermost organic layer out of the plurality of organic layers has a thickness approximately equivalent to that of the lyophilic film as the lowermost layer, and the organic layers as the second or later organic layers have a thickness approximately equivalent to that of each entire laminated film composed of each liquid repellent film on the lower layer side and each lyophilic film on the upper layer side. However, the structure is not limited thereto. That is, combination of each film thickness of each layer in the laminated structure of the dividing wall is not limited to the combination described in the foregoing embodiment and the like.

In addition, in the foregoing embodiment and the like, the description has been specifically given of the structures of the organic EL devices 10R, 10G, and 10B. However, it is not necessary to provide all layers, and other layer may be further provided. Further, in the foregoing embodiment and the like, the description has been given of the display unit including the red and green organic EL devices as an organic EL device other than the blue organic EL device. However, the present disclosure is applicable to the display unit composed of the blue organic EL device and a yellow organic EL device.

Further, in the foregoing embodiment and the like, the description has been given of the active matrix display unit. However, the present disclosure is also applicable to a passive matrix display unit. Furthermore, the configuration of the pixel drive circuit for driving the active matrix is not limited to the configuration described in the foregoing embodiment. If necessary, a capacity device or a transistor may be added. In this case, according to the change of the pixel drive circuit, a necessary drive circuit may be added in addition to the foregoing signal line drive circuit 120 and the foregoing scanning line drive circuit 130.

The present disclosure contains subject matter related to that disclosed in Japanese Priority Patent Application JP 2010-188589 filed in the Japanese Patent Office on Aug. 25, 2010, the entire contents of which is hereby incorporated by reference.

It should be understood by those skilled in the art that various modifications, combinations, sub combinations and alternations may occur depending on design requirements and other factors insofar as they are within the scope of the appended claims or the equivalents thereof.

What is claimed is:

1. An organic EL display unit comprising:
an organic layer provided on a substrate;
a plurality of pixels arranged in a display region on the substrate; and
a dividing wall provided on the substrate and separates adjacent pixels out of the plurality of pixels,
wherein the dividing wall is composed of a laminated structure having two or more types of inorganic material films with different wet characteristics.

2. The organic EL display unit according to claim 1, wherein the dividing wall has a laminated structure composed of a lyophilic film and a liquid repellent film.

3. The organic EL display unit according to claim 2, wherein the lyophilic film and the liquid repellent film are alternately layered.

4. The organic EL display unit according to claim 3, wherein in the laminated structure, a lowermost layer is the lyophilic film, and an uppermost layer is the liquid repellent film.

5. The organic EL display unit according to claim 4,
wherein the organic layer has a laminated structure composed of a plurality of layers,
a lowermost organic layer out of the plurality of layers has a thickness approximately equivalent to that of the lowermost lyophilic film, and
second or later organic layers out of the plurality of layers have a thickness approximately equivalent to that of each entire laminated film composed of each liquid repellent film on the lower layer side and each lyophilic film on the upper layer side.

6. The organic EL display unit according to claim 2, wherein the lyophilic film is formed to project deeper in the internal direction of the pixel than the liquid repellent film.

7. The organic EL display unit according to claim 1 sequentially comprising on the substrate:
an anode;
a hole injection layer, a hole transport layer, a light emitting layer, an electron transport layer, and an electron injection layer as the organic layer; and
a cathode.

8. The organic EL display unit according to claim 7, wherein the hole injection layer, the hole transport layer, and the light emitting layer are provided for the respective pixels.

9. The organic EL display unit according to claim 7, wherein the hole injection layer, the hole transport layer, the light emitting layer, the electron transport layer, and the electron injection layer are respectively made of a polymer material or a low molecular material.

10. The organic EL display unit according to claim 1, wherein the plurality of pixels are composed of a red light emitting pixel, a green light emitting pixel, and a blue light emitting pixel.

11. An electronic device comprising an organic EL display unit,
wherein the organic EL display unit includes:
an organic layer provided on a substrate;
a plurality of pixels arranged in a display region on the substrate; and
a dividing wall provided on the substrate and separates adjacent pixels out of the plurality of pixels, and wherein
the dividing wall is composed of a laminated structure having two or more types of inorganic material films with different wet characteristics.
